(19) United States
(12) Patent Application Publication
(10) Pub. No.: US 2014/0078356 A1
(43) Pub. Date: Mar. 20, 2014

(54) IMAGING SYSTEMS WITH HIGH DIELECTRIC CONSTANT BARRIER LAYER

(71) Applicant: Aptina Imaging Corporation, George Town (KY)

(72) Inventor: Brian Vaartstra, Nampa, ID (US)

(73) Assignee: Aptina Imaging Corporation, George Town (KY)

(21) Appl. No.: 14/030,713

(22) Filed: Sep. 18, 2013

Related U.S. Application Data
(60) Provisional application No. 61/703,653, filed on Sep. 20, 2012.

(51) Int. Cl. H01L 27/146; H04N 9/04

(52) U.S. Cl. CPC H01L 27/1464; H04N 9/045; H01L 27/14627; H01L 27/14685
USPC 348/273; 257/432; 438/70

(57) ABSTRACT

An imaging system may include a camera module with an image sensor having an array of image sensor pixels. The image sensor may include a substrate having an array of photodiodes, an array of microlenses formed over the array of photodiodes, an array of color filter elements interposed between the array of microlenses and the array of photodiodes, and a barrier layer interposed between the array of color filter elements and the array of photodiodes. The barrier layer may be formed from a material with a high dielectric constant. The material used to form the barrier layer may have a dielectric constant above the dielectric constant of silicon dioxide. The barrier layer may replace an antireflective coating over the array of photodiodes and may be used in connection with a silicon dioxide passivation layer interposed between the array of photodiodes and the barrier layer.

This application claims the benefit of provisional patent application No. 61/703,653, filed Sep. 20, 2012, which is hereby incorporated by reference herein in its entirety.

### BACKGROUND

This relates generally to imaging devices, and more particularly, to imaging devices with high dielectric constant barrier layers.

Modern electronic devices such as cellular telephones, cameras, and computers often use digital image sensors. Imagers (i.e., image sensors) may be formed from image sensing pixels. Each pixel may include a photosensor such as a photodiode that receives incident photons (light) and converts the photons into electrical signals. Image sensors are sometimes designed to provide images to electronic devices using a Joint Photographic Experts Group (JPEG) format or any other suitable image format.

In conventional backside illumination (BSI) image sensors, a color filter array is formed over the photodiodes to provide each pixel with sensitivity to a certain range of wavelengths. An array of microlenses is typically formed over the color filter array. Light enters the microlenses and travels through the color filters to the photodiodes. Each photodiode converts incident photons (light) into electrical signals which are then passed through additional imaging system circuitry.

While BSI image sensors enable smaller pixel sizes without the optical losses that are often associated with standard front-side illuminated sensors, one concern of BSI image sensors is the close proximity of color filter materials to the active silicon of the photodiodes. If care is not taken, the ionic contaminants that are intrinsic to color filter pigments and the high refractive index of the silicon may result in reflective losses at the silicon surface.

It would therefore be desirable to be able to provide imaging systems with improved optical efficiency.

### BRIEF DESCRIPTION OF THE DRAWINGS

FIG. 1 is a diagram of an illustrative electronic device in accordance with an embodiment of the present invention.

FIG. 2 is a cross-sectional side view of an illustrative portion of a pixel array having a barrier layer in accordance with an embodiment of the present invention.

FIG. 3 is a flow chart showing process steps involved in forming an illustrative pixel array having a barrier layer in accordance with an embodiment of the present invention.

FIG. 4 is a flow chart showing process steps involved in forming an illustrative pixel array having a barrier layer in accordance with an embodiment of the present invention.

FIG. 5 is a block diagram of a processor system employing the embodiments of FIGS. 1-4 in accordance with an embodiment of the present invention.

### DETAILED DESCRIPTION

Electronic devices such as digital cameras, computers, cellular telephones, and other electronic devices include image sensors that gather incoming light to capture an image. The image sensors may include arrays of imaging pixels. The pixels in the image sensors may include photosensitive elements such as photodiodes that convert the incoming light into image signals. Image sensors may have any number of pixels (e.g., hundreds or thousands of pixels or more). A typical image sensor may, for example, have hundreds of thousands or millions of pixels (e.g., megapixels). Image sensors may include control circuitry such as circuitry for operating the imaging pixels and readout circuitry for reading out image signals corresponding to the electric charge generated by the photosensitive elements.

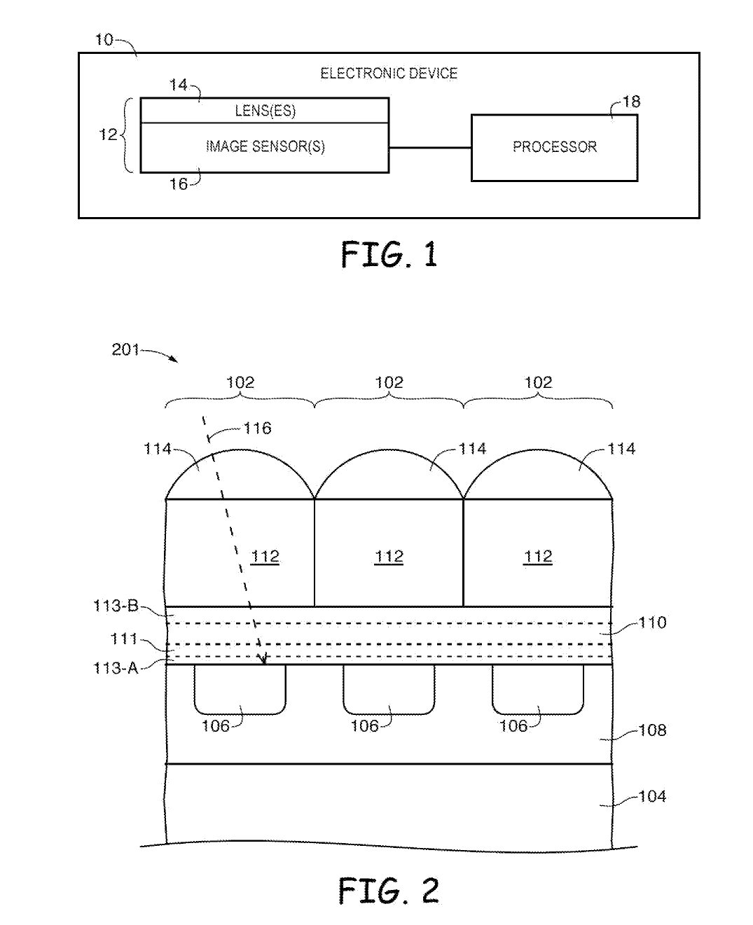

FIG. 1 is a diagram of an illustrative electronic device that uses an image sensor to capture images. Electronic device 10 of FIG. 1 may be a portable electronic device such as a camera, a cellular telephone, a video camera, or other imaging device that captures digital image data. Camera module 12 may be used to convert incoming light into digital image data. Camera module 12 may include one or more lenses 14 and one or more corresponding image sensors 16. During image capture operations, light from a scene may be focused onto image sensor 16 by lens 14. Image sensor 16 provides corresponding digital image data to processing circuitry 18. Image sensor 16 may, for example, be a backside illumination image sensor. If desired, camera module 12 may be provided with an array of lenses 14 and an array of corresponding image sensors 16.

Image sensor 16 may include an array of image sensor pixels and a corresponding array of color filter elements.

Processing circuitry 18 may include one or more integrated circuits (e.g., image processing circuits, microprocessors, storage devices such as random-access memory and non-volatile memory, etc.) and may be implemented using components that are separate from camera module 12 and/or that form part of camera module 12 (e.g., circuits that form part of an integrated circuit that includes image sensors 16 or an integrated circuit within module 12 that is associated with image sensors 16). Image data that has been captured by camera module 12 may be processed and stored using processing circuitry 18. Processed image data may, if desired, be provided to external equipment (e.g., a computer or other device) using wired and/or wireless communications paths coupled to processing circuitry 18.

FIG. 2 shows a cross-sectional side view of a portion of an illustrative image sensor such as a backside illuminated (BSI) image sensor having a pixel array such as pixel array 201. As shown in FIG. 2, pixel array 201 may include an array of image pixels such as image pixels 102. Pixel array 201 may include a circuitry layer such as circuitry layer 104, an array of photosensitive elements such as photodiodes 106 formed in a substrate layer such as substrate layer 108, a barrier layer such as barrier layer 110, an array of color filter elements 112, and an array of microlenses such as microlenses 114. Each microlens 114 directs incident light such as incident light 116 toward an associated photodiode 106. Photodiode 106 may absorb incident light 116 and may produce image signals that correspond to the amount of incident light absorbed. Each color filter 112 that lies below an associated microlens 114 may be a color filter that serves to selectively pass light of particular frequencies. For example, each color filter 112 may only allow red light, green light, or blue light to pass through the color filter and to be received by corresponding photodiode 106. Photodiode 106 may be formed within substrate layer 108 that lies above circuitry layer 104. Substrate layer 108 may be formed from silicon material. Circuitry layer 104 may contain oxide material and metal interconnections.

Color filters 112 (also referred to as color filter elements) may be separated from photodiodes 106 within substrate 108 by barrier layer 110 such that photodiodes 106 are protected from ionic contaminants that are intrinsic to color filter pigments in color filters 112. Barrier layer 110 may be interposed between color filters 112 and substrate layer 108 and may have a thickness of 100-500 Angstroms, 200-400 Angstroms, 100-1000 Angstroms, or any other suitable thickness. Barrier layer 110 may be formed from a transparent material having a high dielectric constant that is above a given threshold. Materials with high dielectric constants are sometimes referred to as “high-k” materials, or materials that have a higher dielectric constant “k” than the dielectric constant for silicon dioxide. For example, high-k materials used to form barrier layer 110 may include materials with dielectric constants above 3.9, between 3.9 and 3000, between 20 and 200, or any other suitable “high-k” dielectric constant. Forming a layer of high-k material on substrate layer 108 may help minimize reflective losses at the surface of substrate layer 108 while also helping to reduce dark current in the image sensor. Barrier layer 110 (sometimes referred to as dielectric layer 110) may be formed from one or more high-k oxides or may be formed from a multi-oxide solid solution. Forming dielectric layer 110 from a multi-oxide solid solution may inhibit crystallization of dielectric layer 110. Barrier layer 110 may be configured to function as a thin surface capacitor and may help repel negative charge at the active silicon surface of photodiodes 106 in substrate layer 108.

High-k oxides that may be used to form barrier layer 110 may include zirconium dioxide (ZrO₂), titanium dioxide (TiO₂), tantalum pentoxide (Ta₂O₅), strontium titanate (SrTiO₃), barium titanate (BaTiO₃), yttrium oxide (Y₂O₃), tellurium dioxide (TeO₂), and zinc oxide (ZnO). Additional materials that may be used to form barrier layer 110 may include lanthanide oxides such as ytterbium oxide (Yb₂O₃), lutetium oxide (Lu₂O₃), and dysprosium oxide (Dy₂O₃). Barrier layer 110 may be formed from solid solutions of any suitable mixtures of the above-mentioned high-k oxides, either with each other, or with materials having lower dielectric constants such as aluminum oxide (Al₂O₃) or silicon dioxide (SiO₂).

Barrier layer 110 may also be formed from one or multiple nanolaminate structures, which are multilayered thin film structures with nanometer dimensions. The nanolaminate structure may be formed from nanolayers of any suitable combination of the above-mentioned high-k oxides with each other or with materials having lower dielectric constants such as such as aluminum oxide (Al₂O₃) or silicon dioxide (SiO₂). The thickness of each nanolayer may be 0.2-200 nanometers or 0.2-1000 nanometers. The nanolayers may be deposited using any suitable deposition methods and equipment for depositing nanolayers, such as atomic layer deposition using atomic layer deposition equipment, sputtering using sputtering equipment, or chemical vapor deposition using chemical vapor deposition equipment. The nanolayers may then be laminated together using any suitable lamination method and lamination equipment. For example, a first nanolayer of a high-k oxide may be laminated to a second nanolayer of a different high-k oxide to form a nanolaminate that may be used to form barrier layer 110.

The high-k materials of barrier layer 110 may help minimize reflective losses at the silicon surface substrate 108, thereby eliminating the need for an additional antireflective coating on the surface of substrate 108. This is, however, merely illustrative. If desired, barrier layer 110 may be used in conjunction with an additional antireflective coating such as antireflective coating layer 111. Barrier layer 110 may also be used in conjunction with an optional thin passivation layer such as layer 113-A. Layer 113-A may be a passivation layer formed from SiO₂. Passivation layer 113-A may be interposed between barrier layer 110 and photodiodes 106 and/or may be interposed between barrier layer 110 and color filters 112. If desired, a first passivation layer such as layer 113-A may be interposed between the barrier layer 110 and substrate 108 and a second passivation layer such as layer 113-B may be interposed between the color filters 112 and barrier layer 110.

Any suitable combination and arrangements of barrier layer 110, optional layer 111, optional layer 113-A, and optional layer 113-B may be used: antireflective layer 111 may be interposed between photodiode array 106 and passivation layer 113-A with or without passivation layer 113-B; passivation layer 113-A may be interposed between antireflective layer 111 and photodiode array 106 with or without passivation layer 113-B; barrier layer 110 may be interposed between antireflective layer 111 and passivation layer 113-B with or without passivation layer 113-A; and barrier layer 110 may be interposed between passivation layers 113-A and 113-B with or without antireflective layer 111. There may also be any suitable number of high-k oxide barrier layers 110 interposed between the array of photodiodes 106 and the array of color filters 112.

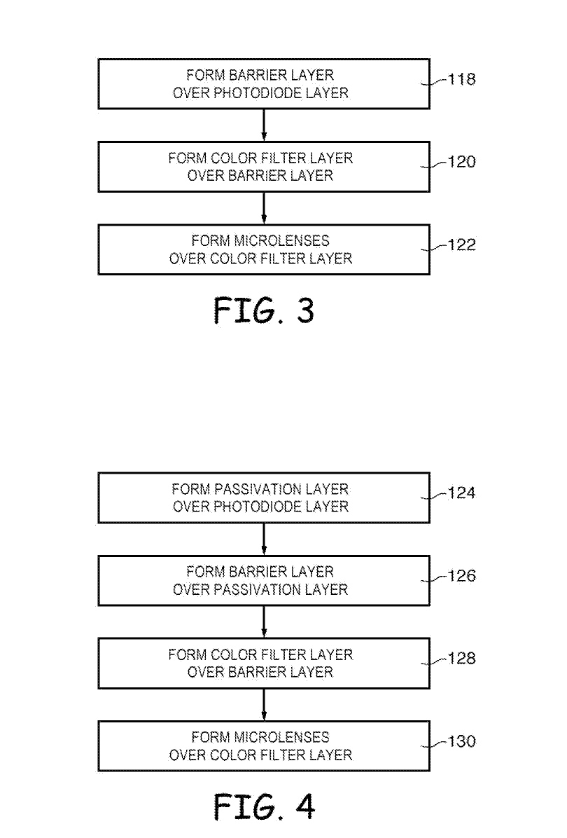

FIG. 3 is a flow chart showing process steps involved in forming a pixel array of a BSI imaging system with barrier layer 110. At step 118, a barrier layer such as barrier layer 110 may be formed over and above photodiodes 106 in substrate 108. The barrier layer may be deposited by physical vapor deposition using physical vapor deposition equipment, chemical vapor deposition using chemical vapor deposition equipment, sputtering using sputtering equipment, and other deposition processes and equipment known in the art. At step 120, a color filter layer such as color filters 112 may be formed over barrier layer 110. At step 122, microlenses such as microlenses 114 may be formed over the color filter layer.

FIG. 4 is a flow chart showing process steps involved in forming a pixel array of a BSI imaging system with a barrier layer and an additional passivation layer. At step 124, a passivation layer may be formed over photodiodes 106 in substrate 108. The passivation layer may be a thin layer of silicon dioxide. At step 126, a barrier layer such as barrier layer 110 may be formed over the passivation layer. At step 128, a color filter layer such as color filters 112 may be formed over the barrier layer. At step 130, microlenses such as microlenses 114 may be formed over the color filter layer.

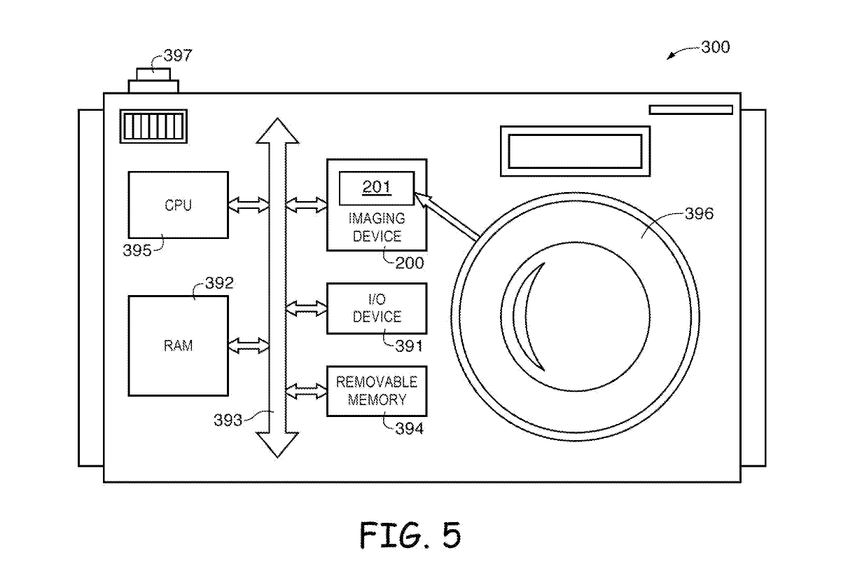

FIG. 5 shows in simplified form a typical processor system 300, such as a digital camera, which includes an imaging device 200. Imaging device 200 may include a pixel array 201 of the type shown in FIGS. 2-4 having a high-k barrier layer interposed between a color filter array and an array of photosensors as described above. Processor system 300 is exemplary of a system having digital circuits that may include imaging device 200. Without being limiting, such a system may include a computer system, still or video camera system, scanner, machine vision, vehicle navigation, video phone, surveillance system, auto focus system, star tracker system, motion detection system, image stabilization system, and other systems employing an imaging device.

Processor system 300, which may be a digital still or video camera system, may include a lens such as lens 396 for focusing an image onto a pixel array such as pixel array 201 when shutter release button 397 is pressed. Processor system 300 may include a central processing unit such as central processing unit (CPU) 395. CPU 395 may be a microprocessor that controls camera functions and one or more image flow functions and communicates with one or more input/output (I/O) devices 391 over a bus such as bus 393. Imaging device 200 may also communicate with CPU 395 over bus 393. System 300 may include random access memory (RAM) 392 and removable memory 394. Removable memory 394 may include flash memory that communicates with CPU 395 over bus 393. Imaging device 200 may be combined with CPU 395, with or without memory storage, on a single integrated circuit or on a different chip. Although bus 393 is illustrated as a single bus, it may be one or more buses or bridges or other communication paths used to interconnect the system components.

Various embodiments have been described illustrating image sensors that have barrier layers formed from high dielectric constant materials. A system may include an image sensor module with an array of image sensor pixels and one or more lenses that focus light onto the array of image sensor pixels (e.g., image pixels arranged in rows and columns). The array of image sensor pixels may include a color filter array interposed between an array of photosensors and an array of microlenses. Image sensors with barrier layers of the type shown in FIGS. 2-4 may be used in an electronic device.

In particular, an image sensor may include a transparent barrier layer interposed between an array of photodiodes and an array of color filter elements. The barrier layer may be formed from a material having a high dielectric constant such as a high-k material. The barrier layer may act as an antireflective coating over the photodiodes. A high-k oxide material, including lanthanide oxides, may be used to form the barrier layer. The barrier layer may, for example, be formed from one or more high-k oxides or may be formed from one more high-k oxides mixed with aluminum oxide or silicon dioxide in a solid multi-oxide solution. The barrier layer may be a nanolaminate structure formed from layers of two or more dielectric materials, at least one of which is a high-k oxide material. The high-k barrier layer may have a thickness of 100-500 Angstroms and may be deposited on an image sensor substrate using any suitable deposition process and equipment known in the art (e.g. physical vapor deposition, chemical vapor deposition, sputtering, etc.).

A passivation layer such as a silicon dioxide passivation layer may be formed between the high-k barrier layer and the array of photodiodes or may be formed between the high-k barrier layer and the color filter layer. If desired, there may be silicon dioxide passivation layers above and below the high-k barrier layer.

The foregoing is merely illustrative of the principles of this invention which can be practiced in other embodiments.

What is claimed is:

1. An image sensor, comprising:
a substrate;
an array of photosensitive elements on the substrate;
an array of color filter elements formed over the array of photosensitive elements;
an array of microlenses formed over the array of color filter elements; and
a transparent barrier layer interposed between the array of photosensitive elements and the array of color filter elements, wherein the transparent barrier layer comprises a material having a high dielectric constant that is above a given threshold.

2. The image sensor defined in claim 1, wherein the transparent barrier layer comprises an antireflective coating.

3. The image sensor defined in claim 1, wherein the material comprises a high-k oxide.

4. The image sensor defined in claim 3, wherein the high-k oxide comprises a high-k oxide selected from the group consisting of: zirconium dioxide, titanium dioxide, tantalum pentoxide, strontium titanate, barium titanate, yttrium oxide, tellurium dioxide, and zinc oxide.

5. The image sensor defined in claim 3, wherein the high-k oxide comprises a lanthanide oxide.

6. The image sensor defined in claim 5, wherein the lanthanide oxide comprises a lanthanide oxide selected from the group consisting of: ytterbium oxide, lutetium oxide, and dysprosium oxide.

7. The image sensor defined in claim 1, wherein the barrier layer comprises a multi-oxide solid solution.

8. The image sensor defined in claim 7, wherein the multi-oxide solution comprises a mixture of at least two different oxide materials each having high dielectric constants.

9. The image sensor defined in claim 7, wherein the multi-oxide solution comprises a mixture of an oxide material having a high dielectric constant and a material selected from the group consisting of: silicon dioxide and aluminum oxide.

10. The image sensor defined in claim 1, wherein the transparent barrier layer comprises a nanolaminate structure of two or more high-k oxides.

11. The image sensor defined in claim 1, further comprising a passivation layer formed from silicon dioxide.

12. The image sensor defined in claim 11, wherein the passivation layer is interposed between the transparent barrier layer and the array of photosensitive elements on the substrate.

13. The image sensor defined in claim 11, wherein the passivation layer is interposed between the transparent barrier layer and the array of color filter elements.

14. The image sensor defined in claim 1, wherein the transparent barrier layer has a thickness of 100-500 Angstroms.

15. A method of forming a backside illuminated image sensor, the method comprising:
obtaining a substrate having an array of photosensitive elements;
depositing a high-k dielectric material over the array of photosensitive elements of the substrate; and
forming a color filter array over the high-k dielectric material.

16. The method defined in claim 15, wherein depositing the high-k dielectric material over the array of photosensitive elements of the substrate comprises depositing an oxide material having a high dielectric constant over the array of photosensitive regions of the substrate.

17. The method defined in claim 16, wherein depositing the oxide material having the high dielectric constant over the array of photosensitive regions of the substrate comprises depositing the oxide material using physical vapor deposition equipment.

18. The method defined in claim 15, further comprising forming a silicon dioxide passivation layer over the array of photosensitive elements of the substrate before depositing the high-k dielectric material.

19. A system, comprising:
a central processing unit;
memory;
input-output circuitry; and
an imaging device, wherein the imaging device comprises:
a pixel array having a plurality of imaging pixels;
a lens that focuses light onto the pixel array;
a microlens array formed over the pixel array;
a color filter array interposed between the pixel array and the microlens array; and
a barrier layer interposed between the pixel array and the color filter array, wherein the barrier layer comprises a material having a high dielectric constant.

20. The system defined in claim 19, wherein the barrier layer is formed from a high-k oxide material.
